(19) United States
(12) Patent Application Publication
(10) Pub. No.: US 2026/0033319 A1
(43) Pub. Date: Jan. 29, 2026

(54) INTEGRATED DEVICE COMPRISING NON-CIRCULAR PILLAR INTERCONNECTS

(71) Applicant: QUALCOMM Incorporated, San Diego, CA (US)

(72) Inventors: Aniket PATIL, San Diego, CA (US); Yujen CHEN, Taichung (TW); Yangyang SUN, San Diego, CA (US)

(21) Appl. No.: 18/784,420

(22) Filed: Jul. 25, 2024

(51) Int. Cl. H01L 23/528; H01L 23/498

(52) U.S. Cl. CPC H01L 23/5283; H01L 23/49816

(57) ABSTRACT

A package comprising a substrate and an integrated device coupled to the substrate. The integrated device comprises a die substrate; and a plurality of pillar interconnects comprising a first plurality of pillar interconnects, wherein at least one pillar interconnect from the first plurality of pillar interconnects comprises a planar cross sectional shape that includes a concave portion.

### FIELD

Various features relate to integrated devices.

### BACKGROUND

A package may include a substrate and integrated devices. These components are coupled together to provide a package that may perform various electrical functions. The performance of integrated devices and/or packages and its components may depend on various factors, including the number of interconnects in the packages and/or the integrated devices. There is an ongoing need to improve the performance of integrated devices and/or packages, while also improving and keeping the form factor of integrated devices and/or packages as small as possible.

### SUMMARY

Various features relate to passive devices and/or integrated devices.

One example provides an integrated device comprising a die substrate; and a plurality of pillar interconnects comprising a first plurality of pillar interconnects, wherein at least one pillar interconnect from the first plurality of pillar interconnects comprises a planar cross sectional shape that includes a concave portion.

Another example provides a package comprising a substrate and an integrated device coupled to the substrate. The integrated device comprises a die substrate; and a plurality of pillar interconnects comprising a first plurality of pillar interconnects, wherein at least one pillar interconnect from the first plurality of pillar interconnects comprises a planar cross sectional shape that includes a concave portion.

Another example provides a method for fabricating an integrated device. The method provides a die substrate. The method forms a plurality of pillar interconnects comprising a first plurality of pillar interconnects, wherein at least one pillar interconnect from the first plurality of pillar interconnects comprises a planar cross sectional shape that includes a concave portion.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional plan view of an exemplary integrated device that includes differently shaped pillar interconnects.

FIG. 2 illustrates a close up cross sectional plan view of an exemplary integrated device that includes differently shaped pillar interconnects.

FIG. 3 illustrates a cross sectional profile view of an exemplary integrated device that includes differently shaped pillar interconnects.

FIG. 4 illustrates a cross sectional profile view of an exemplary package that includes a substrate and an integrated device that includes differently shaped pillar interconnects.

FIGS. 5A-5D illustrate an exemplary sequence for fabricating an integrated device that includes differently shaped pillar interconnects.

FIG. 6 illustrates an exemplary flow diagram of a method for fabricating an integrated device that includes differently shaped pillar interconnects.

FIG. 7 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes an integrated device comprising a die substrate; and a plurality of pillar interconnects comprising a first plurality of pillar interconnects, wherein at least one pillar interconnect from the first plurality of pillar interconnects comprises a planar cross sectional shape that includes a concave portion. The use of pillar interconnects with a concave portion helps increase the lateral size of the pillar interconnects without having to increase the spacing and/or pitch between pillar interconnects. This helps improve the current carrying capabilities of the pillar interconnects, which helps improve the power delivery network (PDN) of the integrated device, while keeping the integrated device as small as possible.

Exemplary Integrated Device Comprising Pillar Interconnects with a Concave Portion

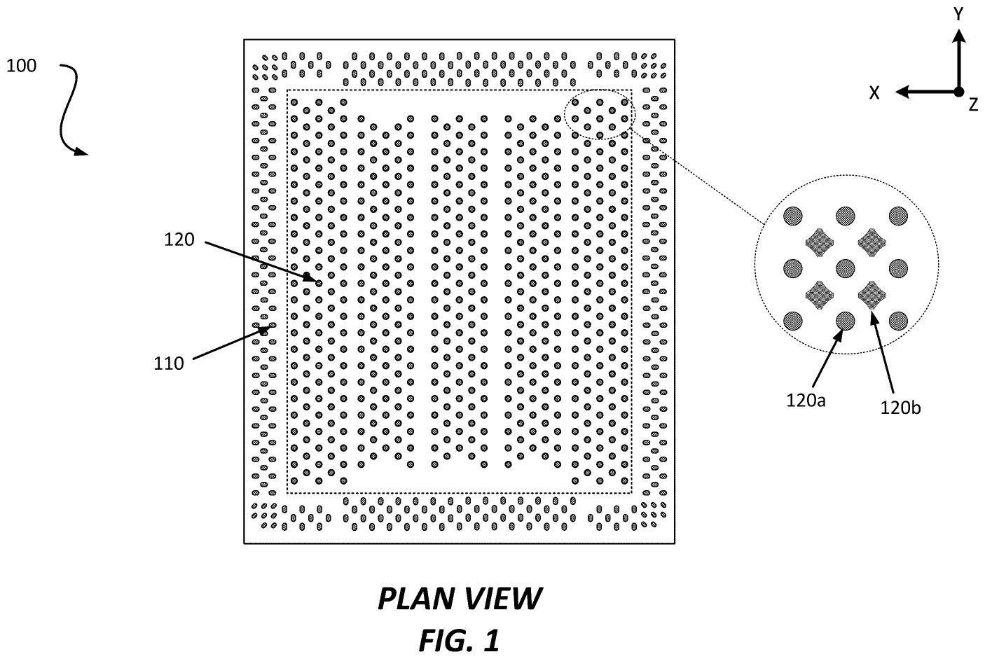

FIG. 1 illustrates a cross sectional profile view of an integrated device 100 that includes pillar interconnects, where at least some of the pillar interconnects include a concave shape, a concave portion and/or a concave surface. The integrated device 100 includes a plurality of pillar interconnects 110 and a plurality of pillar interconnects 120. The plurality of pillar interconnects 110 are located along a periphery of the integrated device 100. At least some of the pillar interconnects from the plurality of pillar interconnects 110 are configured to provide electrical paths for input/output (I/O) signals. A plurality of solder interconnects may be coupled to the plurality of pillar interconnects 110.

The plurality of pillar interconnects 120 are located within an inner region of the integrated device 100. The plurality of pillar interconnects 120 may laterally surround the plurality of pillar interconnects 110. At least some of the pillar interconnects from the plurality of pillar interconnects 120 are configured to provide electrical paths for power (e.g., first power, second power). In some implementations, at least some of the pillar interconnects from the plurality of pillar interconnects 120 are configured to provide electrical paths for ground. A plurality of solder interconnects may be coupled to the plurality of pillar interconnects 120.

The plurality of pillar interconnects 120 includes a plurality of pillar interconnects 120a and a plurality of pillar interconnects 120b. In some implementations, the plurality of pillar interconnects 120a may be configured to provide one or more electrical paths for ground. The plurality of pillar interconnects 120a may include a planar cross section that is circular (e.g., circular shape) and/or approximately circular. For example, at least one pillar interconnect from the plurality of pillar interconnects 120a may include a planar cross section that is circular (e.g., circular shape) and/or approximately circular. The circular shape may include a convex shape, a convex portion and/or a convex surface. In some implementations, the plurality of pillar interconnects 120b may be configured to provide one or more electrical paths for power (e.g., first power, second power, third power). The plurality of pillar interconnects 120b may be configured to provide at least one electrical path for power (e.g., first power, second power, third power). The plurality of pillar interconnects 120b may include a planar cross section that is non-circular. For example, at least one pillar interconnect from the plurality of pillar interconnects 120b may include a planar cross section that has a star shape (e.g., star shape comprising a concave portion). In another example, at least one pillar interconnect from the plurality of pillar interconnects 120b may include a planar cross section that has a cross shape (e.g., cross shape comprising a concave portion). In some implementations, at least one pillar interconnect from plurality of pillar interconnects 120b may include a planar cross section that includes a concave shape. The plurality of pillar interconnects 120b have a planar cross section (e.g., along X-Y plane) that is greater than the planar cross section of the plurality of pillar interconnects 120a, while maintaining the same minimum spacing and/or pitch between pillar interconnects. The increase in the size of the planar cross section means that the plurality of pillar interconnects 120b has increased current carrying capacity, which helps improve the power delivery network (PDN) of the integrated device 100, while maintaining and/or reducing the overall size of the integrated device 100. In some implementations, the use of pillar interconnects with planar cross sections that are circular and pillar interconnects with planar cross sections that are non-circular helps provide optimal performance of the integrated device.

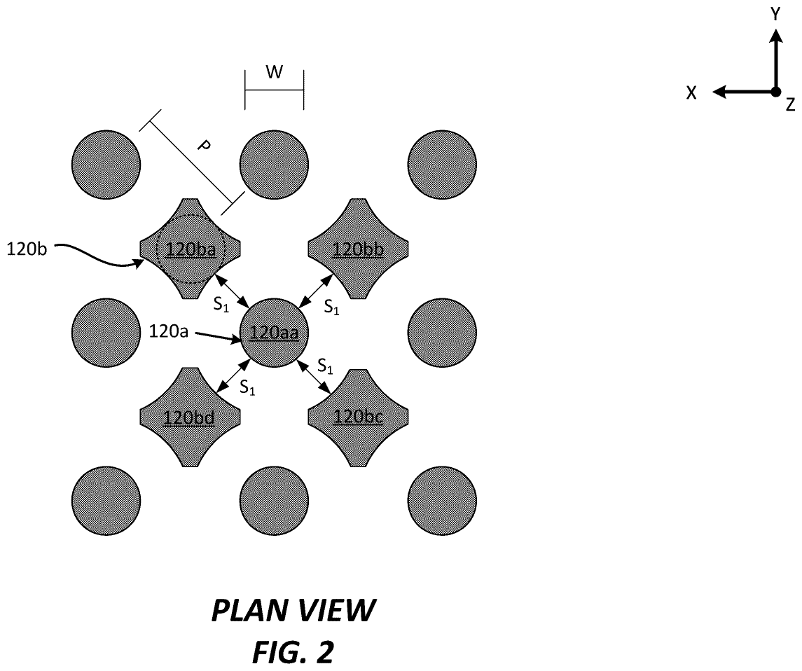

FIG. 2 illustrates a close up view of the integrated device 100 that includes the plurality of pillar interconnects 120a and the plurality of pillar interconnects 120b. As shown in FIG. 2, in some implementations, the plurality of pillar interconnects 120b may be interleaved with the plurality of pillar interconnects 120a. For example, a row of pillar interconnects from the plurality of pillar interconnects 120a may be located between a first row and a second row of pillar interconnects from the plurality of pillar interconnects 120b. In some implementations, a row of pillar interconnects from the plurality of pillar interconnects 120b may be located between a first row and a second row of pillar interconnects from the plurality of pillar interconnects 120a. In some implementations, interleaving the plurality of pillar interconnects 120a and the plurality of pillar interconnects 120b helps provide optimal performance of the integrated device 100.

In some implementations, one or more pillar interconnect from the plurality of pillar interconnects 120a may include a planar cross section that is circular and/or approximately circular. As described above, one or more pillar interconnect from the plurality of pillar interconnects 120b may include a planar cross section that includes a concave shape and/or a concave portion. For example, the side walls of one or more pillar interconnect from the plurality of pillar interconnects 120b may include at least one concave shaped wall (e.g., first concave shaped wall, second concave shaped wall, third concave shaped wall, fourth concave shaped wall) and/or at least one concave surface (e.g., first concave surface, second concave surface, third concave surface, fourth concave surface). As used in the disclosure, a plurality of pillar interconnects that includes a concave shaped wall, a concave shape, a concave portion and/or a concave surface may mean that at least one pillar interconnect from the plurality of pillar interconnects includes at least one concave shaped wall, at least one concave shape, at least one concave portion and/or at least one concave surface.

A pillar interconnect from the plurality of pillar interconnects 120a may have a width (e.g., minimum width, W). A pitch (e.g., minimum pitch, P) may be between (i) a pillar interconnect from the plurality of pillar interconnects 120a and (ii) a pillar interconnect from the plurality of pillar interconnects 120b. FIG. 2 also illustrates that a pillar interconnect 120aa from the plurality of pillar interconnects 120a (which has a circular planar cross section) has a spacing (S1) (e.g., uniform spacing) to adjacent pillar interconnects from the plurality of the pillar interconnects 120b (which has a non-circular planar cross section). For example, a pillar interconnect 120aa from the plurality of pillar interconnects 120a is adjacent to four pillar interconnects (e.g., 120ba, 120bb, 120bc, 120bd) from the plurality of pillar interconnects 120b. The four pillar interconnects from the plurality of pillar interconnects 120b, each includes a concave portion and/or concave surface that faces in the direction of the pillar interconnect 120aa from the plurality of pillar interconnects 120a. The concave surface of the pillar interconnect 120ba is located at a spacing (S1) from the surface of the pillar interconnect 120aa. The concave surface of the pillar interconnect 120bb is located at a spacing (S1) from the surface of the pillar interconnect 120aa. The concave surface of the pillar interconnect 120bc is located at a spacing (S1) from the surface of the pillar interconnect 120aa. The concave surface of the pillar interconnect 120bd is located at a spacing (S1) from the surface of the pillar interconnect 120aa.

As mentioned above, in some implementations, the plurality of pillar interconnects 120a may be configured to provide at least one electrical path for ground. In some implementations, the plurality of pillar interconnects 120b may be configured to provide at least one electrical path for power (e.g., first power, second power, third power). For example, in some implementations, the pillar interconnect 120ba may be configured to provide an electrical path for a first power, and the pillar interconnect 120bb may be configured to provide an electrical path for a second power. In another example, in some implementations, the pillar interconnect 120ba may be configured to provide an electrical path for a first power, and the pillar interconnect 120bb may be configured to provide an electrical path for the first power.

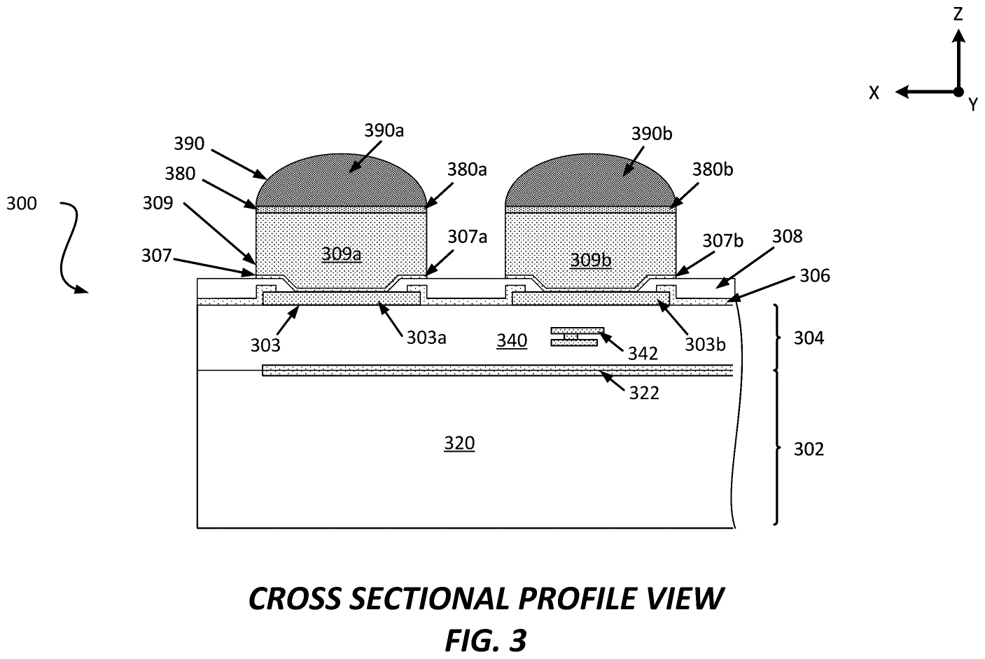

FIG. 3 illustrates an exemplary profile view of an integrated device 300 that includes a plurality of pillar interconnects, where at least some of the pillar interconnects include a concave shape, a concave portion and/or a concave surface.

The integrated device 300 includes a die substrate portion 302, a die interconnection portion 304, a plurality of pad interconnects 303, a plurality of under bump metallization interconnects 307, a plurality of pillar interconnects 309, a plurality of metal interconnects 380, a plurality of solder interconnects 390, a passivation layer 306 and/or a passivation layer 308. One or more of the pillar interconnects from the plurality of pillar interconnects 309 may include a concave shaped wall, a concave shape, a concave portion and/or a concave surface, as described in at least FIGS. 1-2. In some implementations, one or more of the pillar interconnects from the pillar interconnects 309 may include a circular shaped planar cross section, as described in at least FIGS. 1-2.

The die substrate portion 302 includes a die substrate 320 and an active region 322. The die substrate 320 may include silicon (Si). The active region 322 may be formed in the die substrate 320 and/or a surface of the die substrate 320. The active region 322 may include a plurality of logic cells and/or a plurality of transistors. One or more transistors may define a logic cell. The plurality of logic cells may include functioning logic cells when the integrated device is in operation. The plurality of transistors may include functioning transistors. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 320. In some implementations, the die substrate portion 302 may include a plurality of through substrate vias (not shown) that extend through the die substrate 320. A back side metallization portion (not shown) may be coupled to the die substrate 320. The back side metallization portion may include a plurality of back side metallization interconnects that are coupled to the through substrate vias that extend through the die substrate 320.

The die interconnection portion 304 is coupled to the die substrate portion 302. For example, the die interconnection portion 304 is coupled to the die substrate 320. The die interconnection portion 304 includes at least one dielectric layer 340 and a plurality of die interconnects 342. The die interconnection portion 304 may be configured to be electrically coupled to the active region 322. For example, the plurality of die interconnects 342 may be configured to be electrically coupled to the active region 322. Thus, the plurality of die interconnects 342 may be configured to be electrically coupled to the plurality of logic cells and/or plurality of transistors. In some implementations, a back end of line (BEOL) process may be used to fabricate the die interconnection portion 304. The die interconnection portion 304 may be a BEOL die interconnection portion. The plurality of die interconnects 342 may include copper (Cu). The die interconnection portion 304 may be formed over the die substrate portion 302.

The plurality of pad interconnects 303 are coupled to the die interconnection portion 304. The plurality of pad interconnects 303 may be coupled to the plurality of die interconnects 342. The plurality of pad interconnects 303 may include a pad interconnect 303a (e.g., first pad interconnect) and a pad interconnect 303b (e.g., second pad interconnect). The pad interconnect 303a may have a circular planar cross sectional shape and/or an approximate circular planar cross sectional shape. The pad interconnect 303b may have a circular planar cross sectional shape and/or an approximate circular planar cross sectional shape. The pad interconnect 303a may be located laterally to the pad interconnect 303b.

The passivation layer 306 is coupled to the die interconnection portion 304. The passivation layer 306 may be formed and coupled to a surface of the die interconnection portion 304. The passivation layer 306 may be coupled to and touch the at least one dielectric layer 340. The passivation layer 306 may be formed and coupled to part of the plurality of pad interconnects 303. In some implementations, the passivation layer 306 may include silicon nitride (SiN). However, different implementations may use different materials for the passivation layer 306. The passivation layer 306 may include a different material from the at least one dielectric layer 340. The passivation layer 308 may be formed and coupled to a surface of the passivation layer 306. The passivation layer 308 may include a different material from the passivation layer 306.

The plurality of under bump metallization interconnects 307 may be formed and coupled to the plurality of pad interconnects 303. The plurality of under bump metallization interconnects 307 may include an under bump metallization interconnect 307a (e.g., first under bump metallization interconnect) and an under bump metallization interconnect 307b (e.g., second under bump metallization interconnect). The plurality of under bump metallization interconnects 307 may include copper (Cu). The plurality of under bump metallization interconnects 307 may include a seed layer. The under bump metallization interconnect 307a may be coupled to and touch the pad interconnect 303a. The under bump metallization interconnect 307b may be coupled to and touch the pad interconnect 303b. A portion of the plurality of under bump metallization interconnects 307 may be formed and/or located over the passivation layer 308. A portion of under bump metallization interconnect 307a may be formed and/or located over the passivation layer 308. A portion of the under bump metallization interconnect 307b may be formed and/or located over the passivation layer 308.

The plurality of pillar interconnects 309 may correspond to the plurality of pillar interconnects 120. The plurality of pillar interconnects 309 are coupled to the plurality of under bump metallization interconnects 307. At least one pillar interconnect from the plurality of pillar interconnects 309 may include a concave shape, a concave portion and/or a concave surface. For example, at least a portion of the side walls of one or more pillar interconnect from the plurality of pillar interconnects 309 may include a concave shape, a concave portion and/or a concave surface. The plurality of pillar interconnects 309 may be a plurality of bump pillar interconnects. The plurality of pillar interconnects 309 may include a pillar interconnect 309a (e.g., first pillar interconnect) and a pillar interconnect 309b (e.g., second pillar interconnect).

Similarly, the plurality of under bump metallization interconnects 307 may include a plurality of wall under bump metallization interconnects. In some implementations, a wall under bump metallization interconnect may include a concave shape, a concave portion and/or a concave surface.

The plurality of metal interconnects 380 may be optional. The plurality of metal interconnects 380 may include nickel (Ni). The plurality of metal interconnects 380 may include a metal interconnect 380a and a metal interconnect 380b. The plurality of metal interconnects 380 may be coupled to and touch the plurality of pillar interconnects 309. The metal interconnect 380a may be coupled to and touch the pillar interconnect 309a. The metal interconnect 380b may be coupled to and touch the pillar interconnect 309b. The plurality of solder interconnects 390 are coupled to the plurality of pillar interconnects 309 and/or the plurality of metal interconnects 380. The plurality of solder interconnects 390 may include a solder interconnect 390a (e.g., first solder interconnect) and a solder interconnect 390b (e.g., second solder interconnect). The solder interconnect 390a may be coupled to and touch the pillar interconnect 309a and/or the metal interconnect 380a. The solder interconnect 390b may be coupled to and touch the pillar interconnect 309b and/or the metal interconnect 380b. In some implementations, the plurality of metal interconnects 380 may be considered part of the plurality of pillar interconnect 309. The plurality of pillar interconnects 309 and/or the plurality of metal interconnects 380 may be considered as a plurality of bump interconnects.

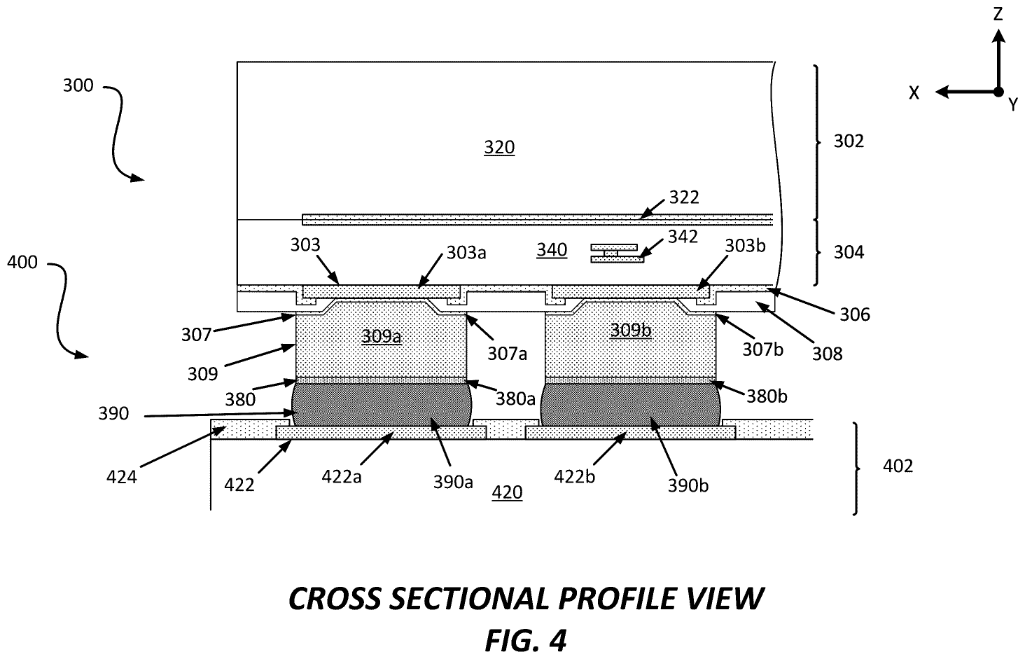

FIG. 4 illustrates a package 400 that includes a substrate 402 and an integrated device 300. The substrate 402 includes at least one dielectric layer 420, a plurality of interconnects 422 and a solder resist layer 424. The plurality of interconnects 422 may include an interconnect 422a and an interconnect 422b. The integrated device 300 is coupled to the substrate 402 through the plurality of pillar interconnects 309, the plurality of metal interconnects 380 and the plurality of solder interconnects 390. For example, the pillar interconnect 309a and the metal interconnect 380a may be coupled to the interconnect 422a through the solder interconnect 390a. The interconnect 422a may include a pad interconnect. The pillar interconnect 309b and the metal interconnect 380b may be coupled to the interconnect 422b through the solder interconnect 390b. As mentioned above, the plurality of metal interconnects 380 may be optional.

It is noted that the use of pillar interconnects that include a concave portion and/or a concave surface is not limited to integrated devices. For example, pillar interconnects that include a concave portion and/or a concave surface, as described in the disclosure may be implemented with passive devices (e.g., silicon passive device, integrated passive devices).

An integrated device (e.g., 100) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 400) may be implemented in a radio frequency (RF) package. The RF package may be a radio frequency front end (RFFE) package. A package (e.g., 400) may be configured to provide Wireless Fidelity (WiFi) communication and/or cellular communication (e.g., 2G, 3G, 4G, 5G). The packages (e.g., 400) may be configured to support Global System for Mobile (GSM) Communications, Universal Mobile Telecommunications System (UMTS), and/or Long-Term Evolution (LTE). The packages (e.g., 400) may be configured to transmit and receive signals having different frequencies and/or communication protocols.

### Exemplary Sequence for Fabricating an Integrated Device

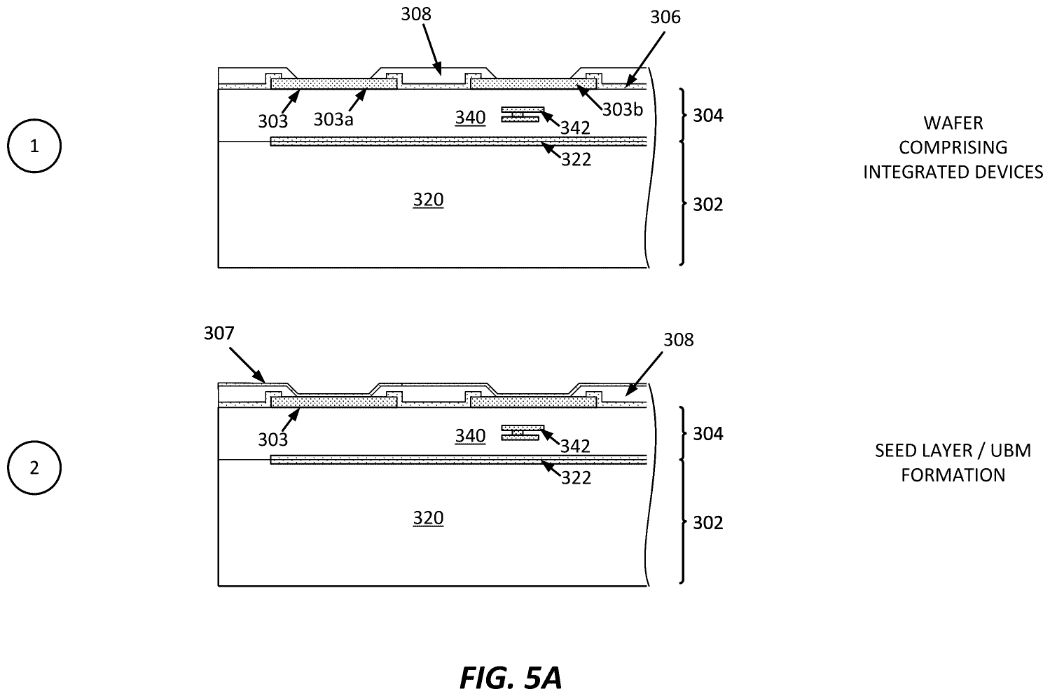

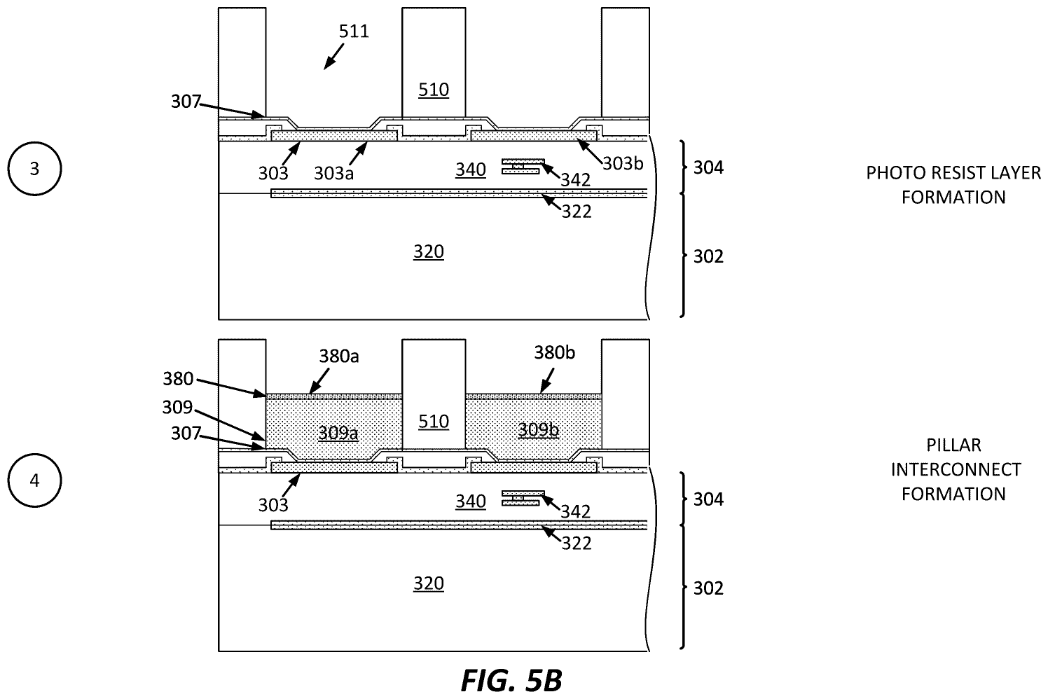

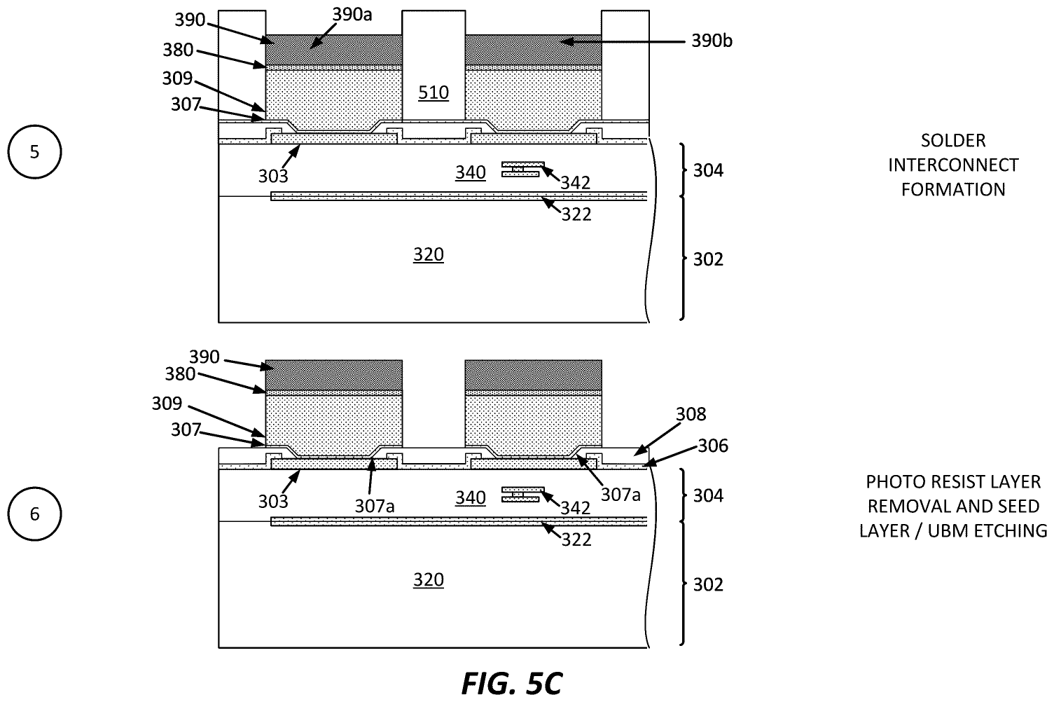

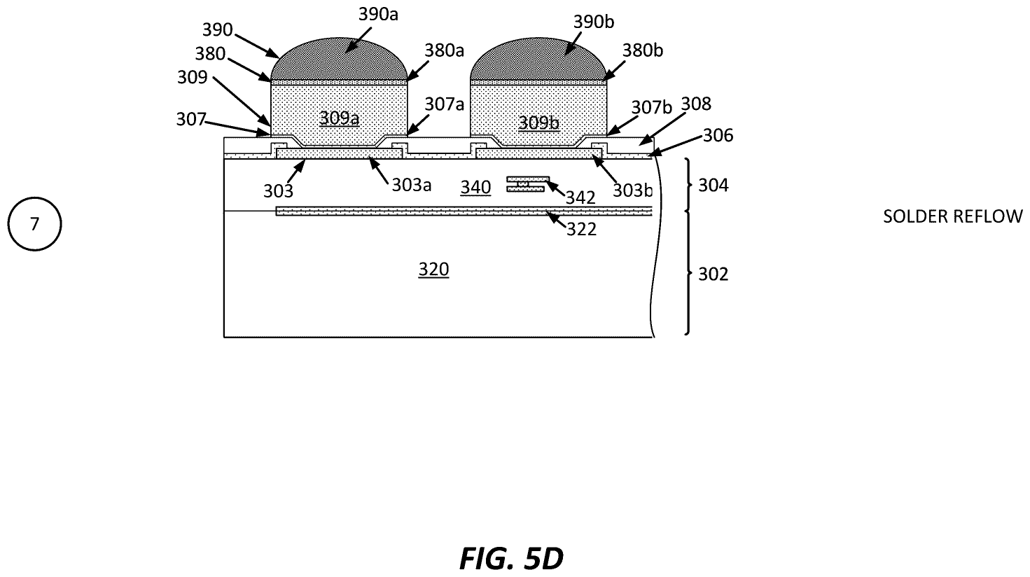

In some implementations, fabricating an integrated device includes several processes. FIGS. 5A-5D illustrate an exemplary sequence for providing or fabricating an integrated device comprising a pillar interconnect. In some implementations, the sequence of FIGS. 5A-5D may be used to provide or fabricate the integrated device 300. However, the process of FIGS. 5A-5D may be used to fabricate any integrated device described in the disclosure.

It should be noted that the sequence of FIGS. 5A-5D may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 5A, illustrates a state after a wafer 500 is provided. The wafer 500 may include a die substrate portion 302, a die interconnection portion 304, a plurality of pad interconnects 303, a passivation layer 306 and/or a passivation layer 308, as described above in at least FIG. 3.

Stage 2 illustrates a state after a seed layer is formed over the wafer 500. The seed layer may be an under bump metallization interconnect (e.g., plurality of under bump metallization interconnects 307). The seed layer may be formed over the passivation layer 308 and the plurality of pad interconnects 303. The seed layer may include copper (Cu). A sputtering process may be used to form the seed layer.

Stage 3, as shown in FIG. 5B, illustrates a state after a photo resist layer 510 is formed over the wafer 500. For example, the photo resist layer 510 may be formed over the seed layer (e.g., over the under bump metallization interconnect 307). The photo resist layer 510 may be patterned to include a plurality of openings 511 in the photo resist layer 510. The photo resist layer 510 may be coated over the wafer 500. A photolithography process may be used to form and define the pattern of the photo resist layer 510. For example, an exposure process and development process may be used to form the plurality of openings 511 in the photo resist layer 510. The plurality of openings 511 may be located over the plurality of pad interconnects 303.

Stage 4 illustrates a state after the plurality of pillar interconnects 309 are formed and coupled to the plurality of under bump metallization interconnects 307 (e.g., formed and coupled to the seed layer). A plating process may be used to form the plurality of pillar interconnects 309. The plurality of pillar interconnects 309 may be formed in the plurality of openings 511 of the photo resist layer 510. In some implementations, the plurality of pillar interconnects 309 may include a planar cross section that includes a concave shape and/or a concave portion. For example, the side walls of one or more pillar interconnect from the plurality of pillar interconnects 309 may include at least one concave surface (e.g., first concave surface, second concave surface, third concave surface, fourth concave surface). The pillar interconnect 309a may be coupled to the pad interconnect 303a, through an under bump metallization interconnect. The pillar interconnect 309b may be coupled to the pad interconnect 303b, through an under bump metallization interconnect. In some implementations, the plurality of pillar interconnects 309 may include a circular planar cross section.

Stage 4 also illustrates a state after the plurality of metal interconnects 380 are formed and coupled to the plurality of pillar interconnects 309. A plating process may be used to form the plurality of metal interconnects 380. As mentioned above, the plurality of metal interconnects 380 may be optional. In some implementations, the plurality of metal interconnects 380 may include a planar cross section that includes a concave shape and/or a concave portion (in a similar manner as the planar cross section of the plurality of pillar interconnects 309). In some implementations, the plurality of metal interconnects 380 may include a circular planar cross section.

Stage 5, as shown in FIG. 5C, illustrates a state after the plurality of solder interconnects 390 are formed and coupled to the plurality of metal interconnects 380. The plurality of solder interconnects 390 may be formed through the plurality of openings 511 of the photo resist layer 510. A pasting process may be used to form the plurality of solder interconnects 390. In some implementations, when the plurality of metal interconnects 380 is optional, the plurality of solder interconnects 390 are formed and coupled to the plurality of pillar interconnects 309 such that the plurality of solder interconnects 390 touch the plurality of pillar interconnects 309.

Stage 6 illustrates a state after the photo resist layer 510 is removed. A strip process may be used to remove the photo resist layer 510. A portion of the seed layer (e.g., portion of the plurality of under bump metallization interconnects 307) may also be etched and/or removed. For example, portions of the seed layer located beneath the photo resist layer 510 may be removed and/or etched.

Stage 7, as shown in FIG. 5D, illustrates a state after a solder reflow process. The solder reflow process may be optional. The solder reflow process bonds and/or couples the plurality of solder interconnects 390 to the plurality of metal interconnects 380. When the plurality of metal interconnects 380 is optional, the solder reflow process bonds and/or couples the plurality of solder interconnects 390 to the plurality of pillar interconnects 309.

### Exemplary Flow Diagram of a Method for Fabricating an Integrated Device

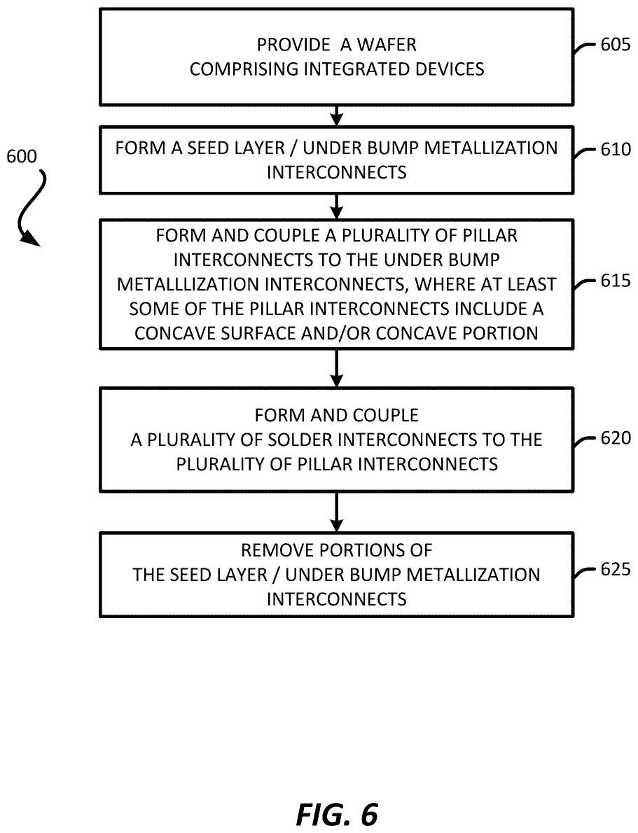

In some implementations, fabricating an integrated device includes several processes. FIG. 6 illustrates an exemplary flow diagram of a method 600 for providing or fabricating an integrated device. In some implementations, the method 600 of FIG. 6 may be used to provide or fabricate the integrated device 300 of FIG. 3. However, the method 600 may be used to provide or fabricate any other integrated devices.

It should be noted that the method 600 of FIG. 6 may combine one or more processes in order to simplify and/or clarify the method for providing or fabricating an integrated device. In some implementations, the order of the processes may be changed or modified.

The method provides (at 605) a wafer that includes integrated devices. Stage 1 of FIG. 5A, illustrates and describes an example of a state after a wafer 500 is provided. The wafer 500 may include a die substrate portion 302, a die interconnection portion 304, a plurality of pad interconnects 303, a passivation layer 306 and/or a passivation layer 308, as described above in at least FIG. 3.

The method forms (at 610) a seed layer. Stage 2 of FIG. 5A, illustrates and describes an example of a state after a seed layer is formed over the wafer 500. The seed layer may be an under bump metallization interconnect (e.g., plurality of under bump metallization interconnects 307). The seed layer may be formed over the passivation layer 308 and the plurality of pad interconnects 303. The seed layer may include copper (Cu). A sputtering process may be used to form the seed layer.

The method forms (at 615) a plurality of pillar interconnects, where at least some of pillar interconnects have a planar cross section that includes a concave portion, a concave shape and/or a concave surface. Stage 3 of FIG. 5B, illustrates and describes an example of a state after a photo resist layer 510 is formed over the wafer 500. For example, the photo resist layer 510 may be formed over the seed layer (e.g., over the under bump metallization interconnect 307). The photo resist layer 510 may be patterned to include a plurality of openings 511 in the photo resist layer 510. The photo resist layer 510 may be coated over the wafer 500. A photolithography process may be used to form and define the pattern of the photo resist layer 510. For example, an exposure process and development process may be used to form the plurality of openings 511 in the photo resist layer 510. The plurality of openings 511 may be located over the plurality of pad interconnects 303.

Stage 4 of FIG. 5B, illustrates and describes an example of a state after the plurality of pillar interconnects 309 are formed and coupled to the plurality of under bump metallization interconnects 307 (e.g., formed and coupled to the seed layer). A plating process may be used to form the plurality of pillar interconnects 309. The plurality of pillar interconnects 309 may be formed in the plurality of openings 511 of the photo resist layer 510. In some implementations, the plurality of pillar interconnects 309 may include a planar cross section that includes a concave shape and/or a concave portion. For example, the side walls of one or more pillar interconnect from the plurality of pillar interconnects 309 may include at least one concave surface (e.g., first concave surface, second concave surface, third concave surface, fourth concave surface). The pillar interconnect 309a may be coupled to the pad interconnect 303a, through an under bump metallization interconnect. The pillar interconnect 309b may be coupled to the pad interconnect 303b, through an under bump metallization interconnect. In some implementations, the plurality of pillar interconnects 309 may include a circular planar cross section.

Stage 4 of FIG. 5B, also illustrates and describes an example of a state after the plurality of metal interconnects 380 are formed and coupled to the plurality of pillar interconnects 309. A plating process may be used to form the plurality of metal interconnects 380. As mentioned above, the plurality of metal interconnects 380 may be optional. In some implementations, the plurality of metal interconnects 380 may be considered part of the plurality of pillar interconnects 309. In some implementations, the plurality of metal interconnects 380 may include a planar cross section that includes a concave shape and/or a concave portion (in a similar manner as the planar cross section of the plurality of pillar interconnects 309). In some implementations, the plurality of metal interconnects 380 may include a circular planar cross section.

The method forms (at 620) a plurality of solder interconnects to the plurality of pillar interconnects and/or the plurality of metal interconnects 380 Stage 5 of FIG. 5C, illustrates and describes an example of a state after the plurality of solder interconnects 390 are formed and coupled to the plurality of metal interconnects 380. The plurality of solder interconnects 390 may be formed through the plurality of openings 511 of the photo resist layer 510. A pasting process may be used to form the plurality of solder interconnects 390. In some implementations, when the plurality of metal interconnects 380 is optional, the plurality of solder interconnects 390 are formed and coupled to the plurality of pillar interconnects 309 such that the plurality of solder interconnects 390 touch the plurality of pillar interconnects 309.

The method removes (at 625) the photo resist layer and/or the seed layer. Stage 6 of FIG. 5C, illustrates and describes an example of a state after the photo resist layer 510 is removed. A strip process may be used to remove the photo resist layer 510. A portion of the seed layer (e.g., portion of the plurality of under bump metallization interconnects 307) may also be etched and/or removed. For example, portions of the seed layer located beneath the photo resist layer 510 may be removed and/or etched.

After the photo resist layer is removed and/or the seed layer is removed, the method may perform a solder reflow process. Stage 7 of FIG. 5D, illustrates and describes an example of a state after a solder reflow process. The solder reflow process may be optional. The solder reflow process bonds and/or couples the plurality of solder interconnects 390 to the plurality of metal interconnects 380. When the plurality of metal interconnects 380 is optional, the solder reflow process bonds and/or couples the plurality of solder interconnects 390 to the plurality of pillar interconnects 309.

### Exemplary Electronic Devices

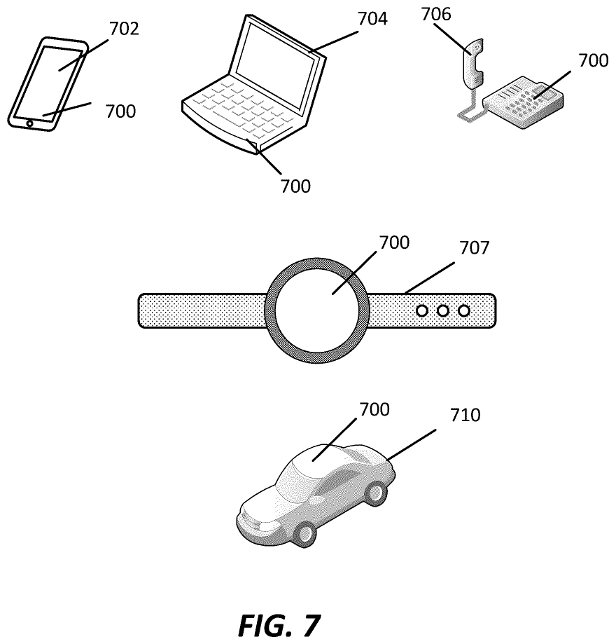

FIG. 7 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 702, a laptop computer device 704, a fixed location terminal device 706, a wearable device 708, or automotive vehicle 710 may include a device 700 as described herein. The device 700 may be, for example, any of the devices and/or integrated circuit (IC) packages described herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5D, and 6-7 may be rearranged and/or combined into a single component, process, feature or function or embodied in several components, processes, or functions. Additional elements, components, processes, and/or functions may also be added without departing from the disclosure. It should also be noted FIGS. 1-4, 5A-5D, and 6-7 and its corresponding description in the present disclosure is not limited to dies and/or ICs. In some implementations, FIGS. 1-4, 5A-5D, and 6-7 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die substrate; and a plurality of pillar interconnects comprising a first plurality of pillar interconnects, wherein at least one pillar interconnect from the first plurality of pillar interconnects comprises a planar cross sectional shape that includes a concave portion.

Aspect 2: The integrated device of aspect 1, wherein the first plurality of pillar interconnects comprises at least one pillar interconnect with a concave shaped wall.

Aspect 3: The integrated device of aspect 1, wherein the first plurality of pillar interconnects comprises at least one pillar interconnect with a planar cross sectional shape that includes a cross shape.

Aspect 4: The integrated device of aspects 1 through 3, wherein the first plurality of pillar interconnects are configured to provide at least one electrical path for power.

Aspect 5: The integrated device of aspects 1 through 4, wherein the plurality of pillar interconnects further comprise a second plurality of pillar interconnects comprising a planar cross sectional shape that includes a circular shape.

Aspect 6: The integrated device of aspect 5, wherein the first plurality of pillar interconnects and the second plurality of pillar interconnects are arranged in an interleaved manner.

Aspect 7: The integrated device of aspects 1 through 6, wherein the first plurality of pillar interconnects comprises a first plurality of core pillar interconnects.

Aspect 8: The integrated device of aspects 1 through 7, wherein the die substrate includes an active region comprising a plurality of logic cells.

Aspect 9: The integrated device of aspect 8, further comprising a dic interconnection portion coupled to the die substrate.

Aspect 10: The integrated device of aspect 9, further comprising a plurality of pad interconnects; and a plurality of under bump metallization interconnects coupled to (i) the plurality of pad interconnects and (ii) the plurality of pillar interconnects.

Aspect 11: A package comprising a substrate; and an integrated device coupled to the substrate, wherein the integrated device comprises a die substrate; and a plurality of pillar interconnects comprising a first plurality of pillar interconnects, wherein at least one pillar interconnect from the first plurality of pillar interconnects comprises a planar cross sectional shape that includes a concave portion.

Aspect 12: The package of aspect 11, wherein the first plurality of pillar interconnects comprises at least one pillar interconnect with a concave shaped wall.

Aspect 13: The package of aspect 11, wherein the first plurality of pillar interconnects comprises at least one pillar interconnect with a planar cross sectional shape that includes a cross shape.

Aspect 14: The package of aspects 11 through 13, wherein the first plurality of pillar interconnects are configured to provide at least one electrical path for power.

Aspect 15: The package of aspects 11 through 14, wherein the plurality of pillar interconnects further comprise a second plurality of pillar interconnects comprising a planar cross sectional shape that includes a circular shape.

Aspect 16: The package of aspect 15, wherein the first plurality of pillar interconnects and the second plurality of pillar interconnects are arranged in an interleaved manner.

Aspect 17: The package of aspects 11 through 16, wherein the first plurality of pillar interconnects comprises a first plurality of core pillar interconnects.

Aspect 18: The package of aspects 11 through 17, wherein the die substrate includes an active region comprising a plurality of logic cells.

Aspect 19: The package of aspect 18, wherein the integrated device further comprises a die interconnection portion coupled to the die substrate.

Aspect 20: The package of aspect 19, wherein the integrated device further comprises a plurality of pad interconnects; and a plurality of under bump metallization interconnects coupled to (i) the plurality of pad interconnects and (ii) the plurality of pillar interconnects.

Aspect 21: A method for fabricating an integrated device. The method provides a die substrate. The method forms a plurality of pillar interconnects comprising a first plurality of pillar interconnects, wherein at least one pillar interconnect from the first plurality of pillar interconnects comprises a planar cross sectional shape that includes a concave portion.

Aspect 22: The method of aspect 21, wherein the first plurality of pillar interconnects comprises at least one pillar interconnect with a concave shaped wall.

Aspect 23: The method of aspect 21, wherein the first plurality of pillar interconnects comprises at least one pillar interconnect with a planar cross sectional shape that includes a cross shape.

Aspect 24: The method of aspects 21 through 23, wherein the first plurality of pillar interconnects are configured to provide at least one electrical path for power.

Aspect 25: The method of aspects 21 through 24, wherein the plurality of pillar interconnects further comprise a second plurality of pillar interconnects comprising a planar cross sectional shape that includes a circular shape.

Aspect 26: The method of aspect 25, wherein the first plurality of pillar interconnects and the second plurality of pillar interconnects are arranged in an interleaved manner.

Aspect 27: The method of aspects 21 through 26, wherein the first plurality of pillar interconnects comprises a first plurality of core pillar interconnects.

Aspect 28: The method of aspects 21 through 27, wherein the die substrate includes an active region comprising a plurality of logic cells.

Aspect 29: The method of aspect 28, further comprising forming a die interconnection portion coupled to the die substrate, wherein the die interconnection is located between the die substrate and the plurality of pillar interconnects

Aspect 30: The method of aspect 29, further comprising a plurality of pad interconnects; and a plurality of under bump metallization interconnects coupled to (i) the plurality of pad interconnects and (ii) the plurality of pillar interconnects.

Aspect 31: The method of aspects 21 through 30, wherein the integrated device is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 32: The integrated device of aspects 1 through 10, wherein the integrated device is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 33: The package of aspects 11 through 20, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate; and
a plurality of pillar interconnects comprising a first plurality of pillar interconnects, wherein at least one pillar interconnect from the first plurality of pillar interconnects comprises a planar cross sectional shape that includes a concave portion.

2. The integrated device of claim 1, wherein the first plurality of pillar interconnects comprises at least one pillar interconnect with a concave shaped wall.

3. The integrated device of claim 1, wherein the first plurality of pillar interconnects comprises at least one pillar interconnect with a planar cross sectional shape that includes a cross shape.

4. The integrated device of claim 1, wherein the first plurality of pillar interconnects are configured to provide at least one electrical path for power.

5. The integrated device of claim 1, wherein the plurality of pillar interconnects further comprise a second plurality of pillar interconnects comprising a planar cross sectional shape that includes a circular shape.

6. The integrated device of claim 5, wherein the first plurality of pillar interconnects and the second plurality of pillar interconnects are arranged in an interleaved manner.

7. The integrated device of claim 1, wherein the first plurality of pillar interconnects comprises a first plurality of core pillar interconnects.

8. The integrated device of claim 1, wherein the die substrate includes an active region comprising a plurality of logic cells.

9. The integrated device of claim 8, further comprising a die interconnection portion coupled to the die substrate.

10. The integrated device of claim 9, further comprising:
a plurality of pad interconnects; and
a plurality of under bump metallization interconnects coupled to (i) the plurality of pad interconnects and (ii) the plurality of pillar interconnects.

11. A package comprising:
a substrate; and
an integrated device coupled to the substrate, wherein the integrated device comprises:
a die substrate; and
a plurality of pillar interconnects comprising a first plurality of pillar interconnects, wherein at least one pillar interconnect from the first plurality of pillar interconnects comprises a planar cross sectional shape that includes a concave portion.

12. The package of claim 11, wherein the first plurality of pillar interconnects comprises at least one pillar interconnect with a concave shaped wall.

13. The package of claim 11, wherein the first plurality of pillar interconnects comprises at least one pillar interconnect with a planar cross sectional shape that includes a cross shape.

14. The package of claim 11, wherein the first plurality of pillar interconnects are configured to provide at least one electrical path for power.

15. The package of claim 11, wherein the plurality of pillar interconnects further comprise a second plurality of pillar interconnects comprising a planar cross sectional shape that includes a circular shape.

16. The package of claim 15, wherein the first plurality of pillar interconnects and the second plurality of pillar interconnects are arranged in an interleaved manner.

17. The package of claim 11, wherein the first plurality of pillar interconnects comprises a first plurality of core pillar interconnects.

18. The package of claim 11, wherein the die substrate includes an active region comprising a plurality of logic cells.

19. The package of claim 18, wherein the integrated device further comprises a die interconnection portion coupled to the die substrate.

20. The package of claim 19, wherein the integrated device further comprises:
a plurality of pad interconnects; and
a plurality of under bump metallization interconnects coupled to (i) the plurality of pad interconnects and (ii) the plurality of pillar interconnects.
